(19) United States
(12) Patent Application Publication
(10) Pub. No.: US 2022/0379734 A1
(43) Pub. Date: Dec. 1, 2022

(54) VEHICLE HAVING AUTOMATIC SOLAR CHARGING STRUCTURE

(71) Applicant: Sung Pok KIM, Cheonan-si (KR)

(72) Inventor: Sung Pok KIM, Cheonan-si (KR)

(21) Appl. No.: 17/694,941

(22) Filed: Mar. 15, 2022

(30) Foreign Application Priority Data
Jun. 1, 2021 (KR) 10-2021-0071025

(51) Int. Cl. B60L 8/00; H02J 7/00; H02J 7/35; H02S 20/30; H02S 10/40

(52) U.S. Cl. CPC B60L 8/003; H02J 7/00032; H02J 7/0042; H02J 7/35; H02S 20/30; H02S 10/40

(57) ABSTRACT

Provided is a vehicle including a solar panel accommodation part mounted on one side surface among outer surfaces of the vehicle to wind and accommodate a solar panel mounting part; the solar panel mounting part having a structure that is inserted into and accommodated in the solar panel accommodation part, or discharged from one side of the solar panel accommodation part, having a structure that is unfolded to be expanded to an area corresponding to one side surface among an outer peripheral surface of the vehicle after being discharged from the solar panel accommodation part, and configured to mount a plurality of solar cell panels to be spaced apart from each other at predetermined intervals on one side surface; and a controller mounted on the solar panel accommodation part.

### CROSS-REFERENCE TO RELATED APPLICATION

This application claims priority to and the benefit of Korean Patent Application No. 10-2021-0071025, filed on Jun. 1, 2021, the disclosure of which is incorporated herein by reference in its entirety.

### BACKGROUND

### 1. Field of the Invention

The present disclosure relates to a vehicle including an automatic solar charging structure, and more specifically, to a vehicle including an automatic solar charging structure including a configuration capable of effectively accommodating solar energy and a configuration capable of cleanly protecting a solar cell panel.

### 2. Discussion of Related Art

Generally, an electric vehicle moves by electric energy of a storage battery. According to this, general electricity is used to charge an exhausted storage battery of the electric vehicle. The general electricity is used to recharge the storage battery of the electric vehicle to drive the electric vehicle, but there is a problem in that a recharging time is too long for commercialization.

Further, as a storage battery of a diesel (lead-free gasoline) vehicle and a storage battery of an electric vehicle were consumed, it was impossible to recharge the storage batteries as there was no such structure and device to automatically recharge the storage batteries.

Specifically, in the electric vehicle, high battery efficiency or low battery efficiency decisively affects vehicle performance, such as mileage, speed, and the like.

However, a case in which a conventional electric vehicle should be frequently recharged because the mileage is short when a battery mounted in the vehicle is charged once, and a velocity of the vehicle is low because the vehicle should carry a battery having a large capacity to be driven is indicated as the biggest problem.

In addition, since there are no structure and device for charging the electric vehicle while driving or externally stopped, there are many problems for driving the electric vehicle for a long time.

Accordingly, Laid-Open Utility Model No. 2010-0012946 disclosed in the Korean Intellectual Property Office has been published. This is invented so that a solar cell module which converts eco-friendly power, that is, solar energy, to electric energy, is installed on a sunroof for a vehicle, and electric energy is produced to achieve power supply of the vehicle through the solar cell module even when the vehicle is driven.

However, looking at the conventional patent document, since the solar cell module is installed only on the sunroof and the power generated from the above is also very insufficient, and thus the power is used only for lighting devices of the vehicle, in consideration of facility costs, manufacturing costs of the solar cell module, or the like, there was a problem in that efficiency was significantly low.

Further, since the production efficiency of power required to drive a vehicle is low, it is difficult to apply this to the case in which electricity is a main power source, such as an electric vehicle.

In order to solve these problems, as shown in FIG. 1, a technology capable of storing electricity through sunlight on a roof panel, side and rear glass panels, and a trunk panel of a vehicle even when the vehicle is driven has been developed. However, in the related art shown in FIG. 1, a solar cell panel is always exposed to the outside even in weather in which solar power generation is impossible or in a situation in which the solar power generation is not necessary. Accordingly, in the solar cell panel shown in FIG. 1, for effective solar power generation, the cleanliness of an external surface should be always checked, and the panel has a problem of being easily damaged by an external impact.

Further, the structure shown in FIG. 1 is a structure which should be directly installed on the vehicle, and cannot be applied to other vehicles by separating a configuration including a solar panel. Further, the structure shown in FIG. 1 is a structure that is customized to the size and shape of the vehicle, and has a problem of not being able to be attached to another vehicle having a different size and shape to be used even when separated from the vehicle.

Accordingly, a technology capable of solving the problems according to the above-mentioned related art is necessary.

(Patent Document 1) Korean Registration Patent No. 10-1801249 (Date of registration: Nov. 20, 2017).

### SUMMARY OF THE INVENTION

The present disclosure is directed to providing a vehicle including an automatic solar charging structure including a configuration that can effectively accommodate solar energy to efficiently produce electric energy, and cleanly protect a solar cell panel, and thus stably maintain power generation efficiency using the solar energy.

According to an aspect of the present disclosure, there is provided a vehicle including an automatic solar charging structure including: a solar panel accommodation part mounted on one side surface among outer surfaces of the vehicle to wind and accommodate a solar panel mounting part; the solar panel mounting part having a structure that is inserted into and accommodated in the solar panel accommodation part, or discharged from one side of the solar panel accommodation part, having a structure that is unfolded to be expanded to an area corresponding to one side surface among an outer peripheral surface of the vehicle after being discharged from the solar panel accommodation part, and configured to mount a plurality of solar cell panels to be spaced apart from each other at predetermined intervals on one side surface; the solar cell panels mounted on one side surface of the solar panel mounting part to be spaced apart from each other at the predetermined intervals, and configured to perform solar power generation; and a controller mounted on the solar panel accommodation part, configured to control the operation of the solar panel accommodation part according to a user's intention, and providing electricity acquired from the solar cell panels to the vehicle.

In one embodiment of the present disclosure, the solar panel accommodation part may include: a first accommodation part mounted on an upper surface of a roof of the vehicle; a second accommodation part mounted on a hood upper surface of the vehicle; a third accommodation part mounted on an upper surface of a rear trunk of the vehicle; fourth accommodation parts mounted on side glass windows of the vehicle; and fifth accommodation parts mounted on side surfaces of the vehicle.

In this case, the solar panel mounting part may have a structure of which a shape is elastically deformable along the outer surface of the vehicle on which the solar panel accommodation part is mounted.

In one embodiment of the present disclosure, the solar panel accommodation part may include: a winding roller mounted on one side surface among outer surfaces of the vehicle, and configured to wind the solar panel mounting part around an outer circumferential surface thereof to change an extending length of the solar panel mounting part; and a rotation driving part mounted on the winding roller and configured to rotate the winding roller according to a control signal of the controller.

In one embodiment of the present disclosure, the solar panel accommodation part may include: a winding housing of a hollow-type cylindrical structure that is mounted on one side surface among the outer surfaces of the vehicle, configured to rotatably mount the winding roller therein, and formed with a discharge port through which the solar panel mounting part accommodated therein enters and exits at one side surface; a housing fixing part having a structure that is mounted on one side surface of the winding housing, and configured to detachably fix the winding housing to the outer surface of the vehicle; the winding roller rotatably mounted in the winding housing, and configured to wind the solar panel mounting part around an outer circumferential surface thereof; a rotation driving part mounted at one side of the winding housing and configured to rotate the winding roller according to a control signal of the controller; a pair of extending rails having a structure that is mounted in a state of being adjacent to the discharge port formed at one side of the solar panel accommodation part and being wound at both side surfaces, and drawn out by a user to extend by a predetermined length in a discharging direction of the solar panel mounting part; and a plurality of detachable fixing parts mounted at one sides of the extending rails to be spaced apart from each other at a predetermined interval, and configured to adsorb and fix the extending rails to the outer surface of the vehicle.

In this case, the solar panel mounting part may include: a pair of extending frames having a wire structure that is wound around outer circumferential surfaces of both end portions of the winding roller, having a structure of which a position is changed along the extending rails, and bound to both end portions of the solar cell panel to fix a position of the solar cell panel; and spacing frames mounted between the pair of extending frames in an integrated structure, and configured to maintain an interval between the pair of extending frames at a predetermined distance.

In one embodiment of the present disclosure, the fifth accommodation parts of the solar panel accommodation part may be sequentially mounted to be adjacent to each other in an independent form by 1,000 to 1,400 mm along the side surface of the vehicle.

In one embodiment of the present disclosure, the solar cell panels may be mounted in a form of which portions of both end portions are engaged with each other to overlap each other, and both end portions of the solar cell panels overlapping each other according to the user's intention may be unfolded and sequentially disposed.

In one embodiment of the present disclosure, the vehicle may include: a sunlight amount detector mounted on the outer surface of the vehicle to detect an amount of sunlight incident thereon in real time, and transmit detected data to the controller; a weather information acquisition part mounted in the vehicle and linked to an Internet network to receive real-time weather information and transmit the real-time weather information to the controller; a position change part mounted on the outer surface of the vehicle and configured to change a position of the solar panel accommodation part; and an angle change part configured to change a mounting angle of the solar cell panels mounted on the solar panel mounting part.

In this case, the controller may control operations of the solar panel accommodation part, the position change part, and the angle change part using the sunlight amount detector and the weather information acquisition part, have a built-in wireless communication module interworking with a user's smart device, and provide an operation state of the solar panel accommodation part and a production state of electricity produced from the solar cell panels to the user's smart device using the wireless communication module.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a perspective view illustrating a vehicle according to the related art;

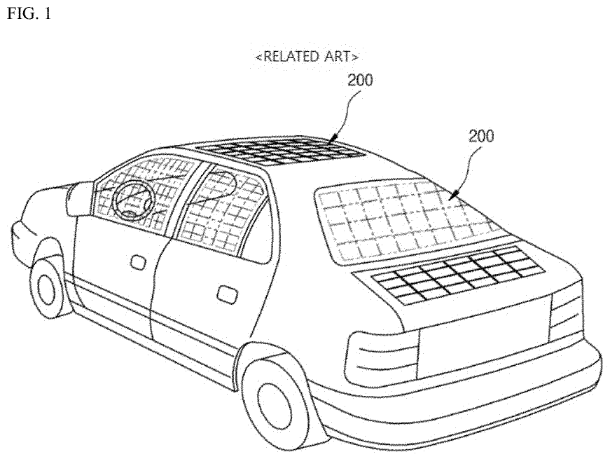

FIG. 2 is a front schematic view illustrating a vehicle including an automatic solar charging structure according to one embodiment of the present disclosure;

FIG. 3 is a perspective view illustrating a solar panel accommodation part, a solar panel mounting part, and a solar cell panel shown in FIG. 2;

FIG. 4 is a front schematic view illustrating a vehicle including an automatic solar charging structure according to another embodiment of the present disclosure;

FIG. 5 is a front schematic view illustrating a vehicle including an automatic solar charging structure according to still another embodiment of the present disclosure;

FIG. 6 is a perspective view illustrating a solar panel accommodation part, a solar panel mounting part, and a solar cell panel of a vehicle according to still another embodiment of the present disclosure;

FIG. 7 is a perspective view illustrating a case in which the configuration shown in FIG. 6 operates; and

FIG. 8 is a control block diagram illustrating a vehicle including an automatic solar charging structure according to still another embodiment of the present disclosure.

### DETAILED DESCRIPTION OF EXEMPLARY EMBODIMENTS

Hereinafter, preferable embodiments of the present disclosure will be described in detail with reference to the drawings. Prior to this, terms or words used in the specification and claims should not understood as being limited to conventional or dictionary meanings, but should be understood as meanings and concepts consistent with the technical spirit of the present disclosure.

Throughout this specification, a case in which a member is said to be located “on” another member includes not only a case in which a member comes into contact with another member but also a case in which another member is present between the two members. Throughout this specification, a case in which a part “includes” a certain component refers to a case in which other components may be further included, rather than excluding other components, unless otherwise disclosed.

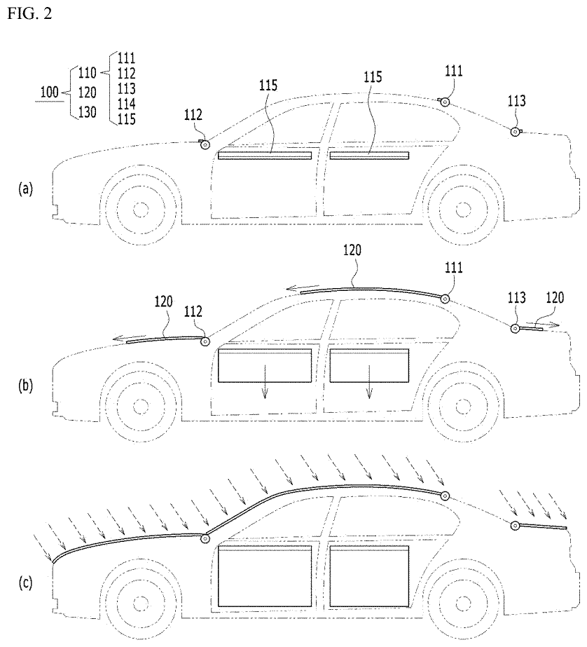

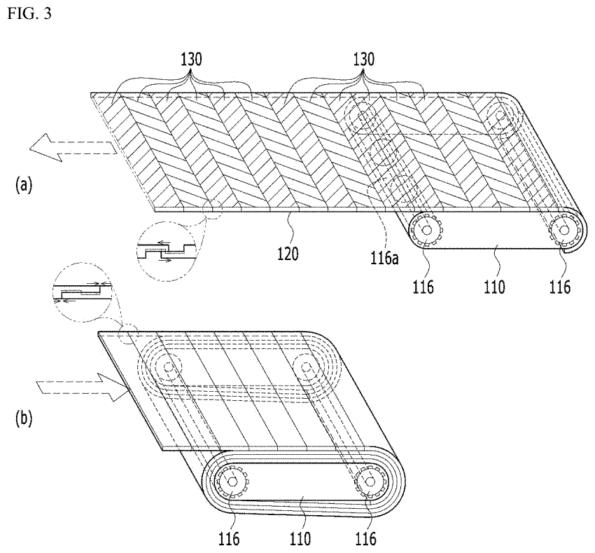

A front schematic view illustrating a vehicle including an automatic solar charging structure according to one embodiment of the present disclosure is shown in FIG. 2, and a perspective view illustrating a solar panel accommodation part, a solar panel mounting part, and a solar cell panel shown in FIG. 2 is shown in FIG. 3.

Referring to these drawings, according to a vehicle 100 including an automatic solar charging structure according to the embodiment, it is possible to provide a vehicle including an automatic solar charging structure, including a configuration capable of effectively accommodating solar energy to efficiently produce electric energy, and cleanly protecting a solar cell panel to stably maintain power generation efficiency using the solar energy by including a solar panel accommodation part 110, a solar panel mounting part 120, solar cell panels 130, and a controller 140 of specific structures.

Hereinafter, each configuration constituting the vehicle 100 according to the embodiment will be described in detail with reference to the drawings.

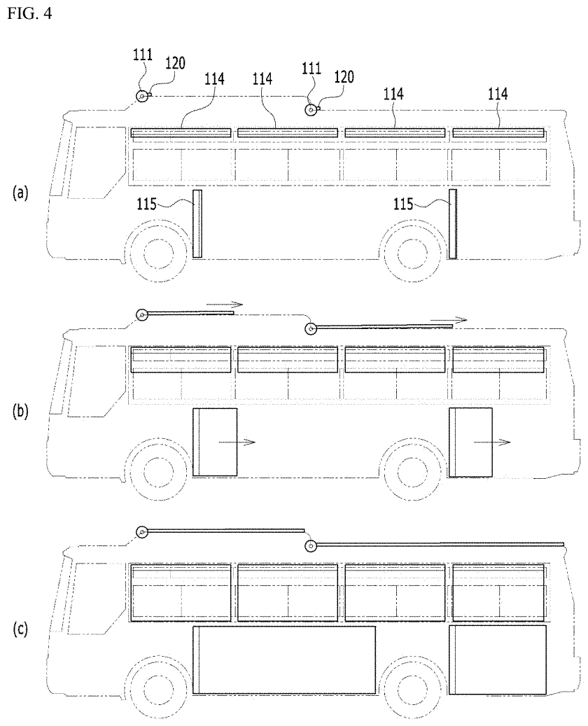

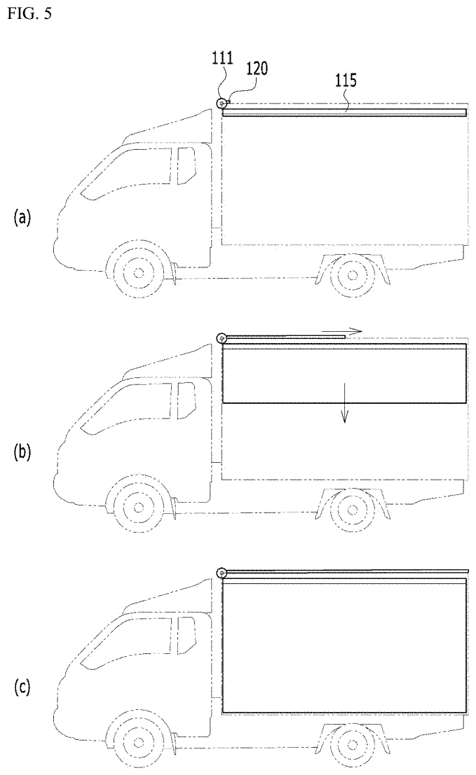

A front schematic view illustrating a vehicle including an automatic solar charging structure according to another embodiment of the present disclosure is shown in FIG. 4, and a front schematic view illustrating a vehicle including an automatic solar charging structure according to still another embodiment of the present disclosure is shown in FIG. 5.

Referring to FIGS. 2 to 5, the vehicle 100 according to the embodiment may be a configuration including the solar panel accommodation part 110, the solar panel mounting part 120, the solar cell panels 130, and the controller 140 of specific structures.

Specifically, the solar panel accommodation part 110 may be a configuration mounted on one side surface among outer surfaces of the vehicle to wind and accommodate the solar panel mounting part 120.

In some cases, as shown in FIG. 3, the solar panel accommodation part 110 according to the embodiment may be a configuration which winds and fixes the solar panel mounting part 120 at the outside thereof.

The solar panel mounting part 120 has a structure that is inserted into and accommodated in the solar panel accommodation part 110, or discharged from one side of the solar panel accommodation part 110, has a structure unfolded to be expanded to an area corresponding to one side surface among an outer peripheral surface of the vehicle after being discharged from the solar panel accommodation part 110, and may mount a plurality of solar cell panels 130 to be spaced apart from each other at predetermined intervals on one side surface.

The plurality of solar cell panels 130 according to the embodiment are configurations mounted on one side surface of the solar panel mounting part 120 to be spaced apart from each other at predetermined intervals, and may perform solar power generation.

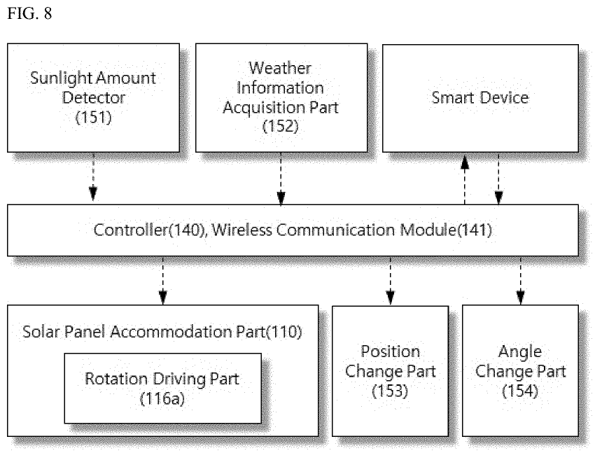

In this case, a controller (140 in FIG. 8) according to the embodiment may be mounted on the solar panel accommodation part 110, may control the operation of the solar panel accommodation part 110 according to a user's intention, and may provide electricity acquired from the solar cell panels 130 to the vehicle.

As shown in FIGS. 2, 4, and 5, the solar panel accommodation part 110 according to the embodiment may be a configuration including a first accommodation part 111 mounted on an upper surface of a roof of the vehicle, a second accommodation part 112 mounted on a hood upper surface of the vehicle, a third accommodation part 113 mounted on an upper surface of a rear trunk of the vehicle, fourth accommodation parts 114 mounted on side glass windows of the vehicle, and fifth accommodation parts 115 mounted on side surfaces of the vehicle.

A large vehicle shown in FIG. 4 may utilize relatively wider side surfaces compared to other vehicles, and in this case, the fifth accommodation parts 115 may be sequentially mounted adjacent to each other in an independent form by 1,000 to 1,400 mm along the side surface of the vehicle.

Further, as shown in FIG. 3, the solar cell panels 130 may be mounted in a form of which portions of both end portions are engaged with each other to overlap each other, and in this case, both end portions overlapping each other according to the user's intention may be unfolded and sequentially disposed.

Meanwhile, the solar panel mounting part 120 may have a structure of which a shape is elastically deformable along the outer surface of the vehicle on which the solar panel accommodation part 110 is mounted.

In this case, according to the embodiment, it is possible to provide a vehicle including an automatic solar charging structure, which may be customized and applied to outer peripheral surfaces of all vehicles having various shapes and sizes by including the solar panel accommodation part 110 including the first accommodation part 111, the second accommodation part 112, the third accommodation part 113, the fourth accommodation parts 114, and the fifth accommodation parts 115 of specific structures, and including the solar panel mounting part 120 of which a shape is elastically deformed along the outer peripheral surfaces of the vehicle, and accordingly, may generate electricity by effectively accommodating sunlight incident on outer surfaces of the vehicle.

Meanwhile, as shown in FIG. 3, the solar panel accommodation part 110 may be a configuration including a winding roller 116 and a rotation driving part 116a having specific structures. The winding roller 116 of the solar panel accommodation part 110 may be mounted on one side surface among outer surfaces of the vehicle, and wind the solar panel mounting part 120 around an outer circumferential surface thereof to change an extending length of the solar panel mounting part 120. Further, the rotation driving part 116a of the solar panel accommodation part 110 is a configuration mounted on the winding roller 116, and may rotate the winding roller 116 according to a control signal of the controller 140.

In this case, as mentioned above, the solar panel accommodation part 110 according to the embodiment may be a configuration which winds and fixes the solar panel mounting part 120 at the outside thereof.

In this case, according to the embodiment, it is possible to provide a vehicle including an automatic solar charging structure, including a configuration capable of stably winding and store the solar cell panel 130 mounted on outer peripheral surfaces of the vehicle by including the solar panel accommodation part 110 including the winding roller 116 and the rotation driving part 116a of specific structures, and thus capable of preventing contamination of the solar cell panel 130 from an external environment.

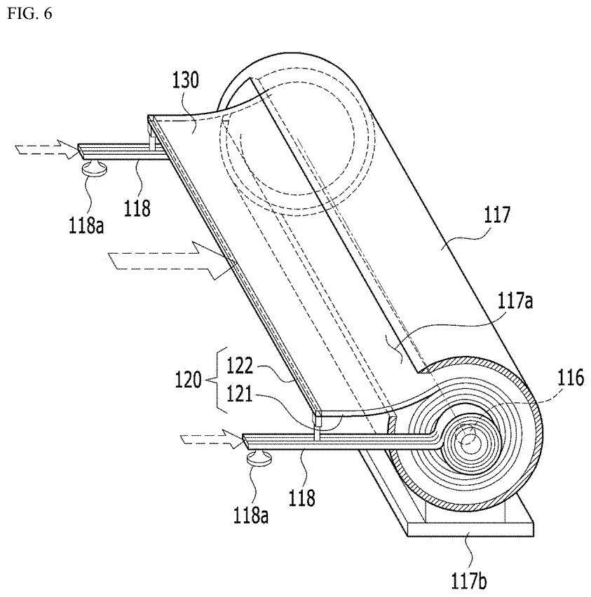

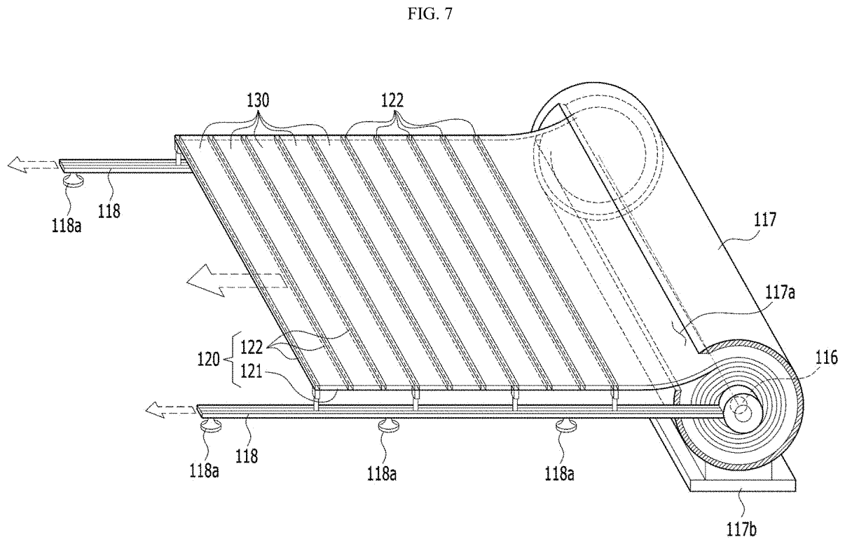

FIG. 6 is a perspective view illustrating a solar panel accommodation part, a solar panel mounting part, and a solar cell panel of a vehicle according to still another embodiment of the present disclosure, FIG. 7 is a perspective view illustrating a case in which the configuration shown in FIG. 6 operates, and FIG. 8 is a control block diagram illustrating a vehicle including an automatic solar charging structure according to still another embodiment of the present disclosure.

Referring to these drawings, the solar panel accommodation part 110 according to the embodiment may be a configuration including a winding housing 117, a housing fixing part 117b, a winding roller 116, a rotation driving part 116a, extending rails 118, and detachable fixing parts 118a of specific structures.

Specifically, the winding housing 117 of the solar panel accommodation part 110 is a configuration mounted on one side surface among outer surfaces of the vehicle, and may have a hollow-type cylindrical structure in which the winding roller 116 is rotatably mounted therein and a discharge port 117a through which the solar panel mounting part 120 accommodated therein may enter and exit is formed on one side surface.

The housing fixing part 117b may be a configuration mounted on one side surface of the winding housing 117, and may have a structure which detachably fixes the winding housing 117 to the outer surface of the vehicle

The winding roller 116 may have a structure which is rotatably mounted in the winding housing, and winds the solar panel mounting part 120 around an outer circumferential surface thereof.

In this case, the rotation driving part 116a mounted on one side of the winding housing 117 may rotate the winding roller 116 according to a control signal of the controller 140.

A pair of extending rails 118 may be a configuration mounted in a state of being adjacent to the discharge port 117a formed at one side of the solar panel accommodation part 110 and being wound at both side surfaces, and may have a structure that is drawn out by a user to extend by a predetermined length in a discharging direction of the solar panel mounting part 120.

Further, the detachable fixing parts 118a may be a configuration mounted at one sides of the extending rails 118 to be spaced apart from each other at a predetermined interval, and may adsorb and fix the extending rails 118 to the outer surface of the vehicle.

Meanwhile, the solar panel mounting part 120 according to the embodiment may be a configuration including extending frames 121 and spacing frames 122 of specific structures.

Specifically, a pair of extending frames 121 may have a wire structure that is wound around outer circumferential surfaces of both end portions of the winding roller 116 or a flexible bar structure, and a structure of which a position is changed along the extending rails 118, and may be bound to both end portions of the solar cell panel 130 to fix a position of the solar cell panel 130.

In this case, the spacing frames 122 may be a configuration mounted between the pair of extending frames 121 in an integrated structure, and may have a structure which maintains an interval between the pair of extending frames 121 at a predetermined distance. In some cases, the spacing frames 122 may be a configuration including a variable structure of which a length may be changed according to the user's intention.

In this case, according to the embodiment, it is possible to provide a vehicle including an automatic solar charging structure, including a configuration capable of stably winding and store the solar cell panel 130 mounted on outer peripheral surfaces of the vehicle by including the solar panel accommodation part 110 including the winding housing 117, the housing fixing part 117b, the winding roller 116, the rotation driving part 116a, the extending rails 118, and the detachable fixing part 118a of specific structures, and the solar panel mounting part 120 including the extending frames 121 and the spacing frames 122 of specific structures to prevent contamination of the solar cell panel 130 from an external environment.

FIG. 8 is a control block diagram illustrating a vehicle including an automatic solar charging structure according to still another embodiment of the present disclosure.

Referring to FIG. 8 together with FIGS. 6 and 7, a vehicle 100 according to the embodiment may be a configuration further including a sunlight amount detector 151, a weather information acquisition part 152, a position change part 153, and an angle change part 154 which perform specific roles.

Specifically, the sunlight amount detector 151 of the vehicle according to the embodiment may be a configuration mounted on the outer surface of the vehicle to detect an amount of sunlight incident thereon in real time, and transmit detected data to the controller.

The weather information acquisition part 152 may be a configuration mounted in the vehicle, and may be linked to an Internet network to receive real-time weather information and transmit the real-time weather information to the controller 140.

The position change part 153 may be a configuration mounted on the outer surface of the vehicle, and may change a position of the solar panel accommodation part 110.

Further, the angle change part 154 may change a mounting angle of the solar cell panel 130 mounted on the solar panel mounting part 120.

In this case, the controller 140 according to the embodiment may control operations of the solar panel accommodation part 110, the position change part 153, and the angle change part 154 using the sunlight amount detector 151 and the weather information acquisition part 152.

Further, the controller 140 according to the embodiment may be a configuration in which there is a built-in wireless communication module 141 interworking with a user's smart device, and may provide an operation state of the solar panel accommodation part 110 and a production state of electricity produced from the solar cell panels 130 to the user's smart device using the wireless communication module 141.

In this case, according to the embodiment, it is possible to provide a vehicle including an automatic solar charging structure, capable of controlling the solar panel accommodation part 110, the position change part 153, and the angle change part 154 using the sunlight amount detector 151 and the weather information acquisition part 152, capable of providing an operation state of the solar panel accommodation part 110 and a production state of electricity produced from the solar cell panels 130 to the user's smart device using the wireless communication module 141 by including the sunlight amount detector and the weather information acquisition part which perform specific roles, and the controller 140 which performs specific control, and thus capable of significantly improving solar power generation efficiency by actively changing the structure according to a weather condition.

As described above, according to a vehicle including an automatic solar charging structure of the present disclosure, it is possible to provide a vehicle including an automatic solar charging structure including a configuration capable of effectively accommodating solar energy to efficiently produce electric energy, and capable of cleanly protecting a solar cell panel to stably maintain power generation efficiency using the solar energy by including a solar panel accommodation part, a solar panel mounting part, a solar cell panel and a controller of specific structures.

Further, according to the vehicle including an automatic solar charging structure of the present disclosure, it is possible to provide a vehicle including an automatic solar charging structure, which can be customized and applied to outer peripheral surfaces of all vehicles having various shapes and sizes by including a solar panel accommodation part including a first accommodation part, a second accommodation part, a third accommodation part, a fourth accommodation part, and a fifth accommodation part of specific structures, and including a solar panel mounting part of which a shape is elastically deformed along an outer peripheral surfaces of the vehicle, and accordingly, can generate electricity by effectively accommodating sunlight incident on outer surfaces of the vehicle.

In addition, according to the vehicle including an automatic solar charging structure of the present disclosure, it is possible to provide a vehicle including an automatic solar charging structure, including a configuration capable of stably winding and store a solar cell panel mounted on outer peripheral surfaces of the vehicle by including a solar panel accommodation part including a winding roller and a rotation driving part of specific structures to prevent contamination of the solar cell panel from an external environment.

In addition, according to the vehicle including an automatic solar charging structure of the present disclosure, it is possible to provide a vehicle including an automatic solar charging structure, including a configuration capable of stably winding and store a solar cell panel mounted on outer peripheral surfaces of the vehicle by including a solar panel accommodation part including a winding housing, a housing fixing part, a winding roller, a rotation driving part, extending rails, and detachable fixing parts of specific structures, and a solar panel mounting part including extending frames and spacing frames of specific structures to prevent contamination of the solar cell panel from an external environment.

In addition, according to the vehicle including an automatic solar charging structure of the present disclosure, it is possible to provide a vehicle including an automatic solar charging structure, capable of controlling operations of a solar panel accommodation part, a position change part, and an angle change part using a sunlight amount detector and a weather information acquisition part, and capable of providing an operation state of the solar panel accommodation part and a production state of electricity produced from the solar cell panels to a user's smart device using a wireless communication module by including the sunlight amount detector and the weather information acquisition part which perform specific roles, and a controller which performs specific control to significantly improve solar power generation efficiency by actively changing the structure according to a weather condition.

In the above detailed description of the present disclosure, only specific embodiments thereof have been described. However, it should be understood that the present disclosure is not limited to specific forms mentioned in the detailed description, but includes all modifications, equivalents, and substitutions within the spirit and the scope of the present disclosure defined by the appended claims.

That is, the present disclosure is not limited to the above-described specific embodiments and descriptions, and various modifications may be performed by those skilled in the art without departing from the gist of the present disclosure claimed in the claims, and those modifications should be within the scope of the present disclosure.

What is claimed is:

1. A vehicle comprising:
a solar panel accommodation part (110) mounted on one side surface among outer surfaces of the vehicle to wind and accommodate a solar panel mounting part (120);
the solar panel mounting part (120) having a structure that is inserted into and accommodated in the solar panel accommodation part (110) or discharged from one side of the solar panel accommodation part (110), having a structure that is unfolded to be expanded to an area corresponding to one side surface among an outer peripheral surface of the vehicle after being discharged from the solar panel accommodation part (110), and configured to mount a plurality of solar cell panels (130) to be spaced apart from each other at predetermined intervals on one side surface;
the solar cell panels (130) mounted on the one side surface of the solar panel mounting part (120) to be spaced apart from each other at the predetermined intervals, and configured to perform solar power generation; and
a controller (140) mounted on the solar panel accommodation part (110), configured to control an operation of the solar panel accommodation part (110) according to a user's intention, and providing electricity acquired from the solar cell panels (130) to the vehicle.

2. The vehicle of claim 1, wherein the solar panel accommodation part (110) includes:
a first accommodation part (111) mounted on an upper surface of a roof of the vehicle; a second accommodation part (112) mounted on a hood upper surface of the vehicle; a third accommodation part (113) mounted on an upper surface of a rear trunk of the vehicle; fourth accommodation parts (114) mounted on side glass windows of the vehicle; and fifth accommodation parts (115) mounted on side surfaces of the vehicle; and
the solar panel mounting part (120) has a structure of which a shape is elastically deformable along the outer surface of the vehicle on which the solar panel accommodation part (110) is mounted.

3. The vehicle of claim 2, wherein the solar panel accommodation part (110) includes:
a winding housing (117) of a hollow-type cylindrical structure that is mounted on the one side surface among the outer surfaces of the vehicle, configured to rotatably mount a winding roller (116) therein, and formed with a discharge port (117a) through which the solar panel mounting part (120) accommodated therein enters and exits at one side surface;
a housing fixing part (117b) having a structure that is mounted on one side surface of the winding housing (117), and configured to detachably fix the winding housing (117) to the outer surface of the vehicle;
the winding roller (116) rotatably mounted in the winding housing, and configured to wind the solar panel mounting part (120) around an outer circumferential surface thereof;
a rotation driving part (116a) mounted at one side of the winding housing (117) and configured to rotate the winding roller (116) according to a control signal of the controller (140);
a pair of extending rails (118) having a structure that is mounted in a state of being adjacent to the discharge port (117a) formed at one side of the solar panel accommodation part (110) and being wound at both side surfaces, and drawn out by a user to extend by a predetermined length in a discharging direction of the solar panel mounting part (120); and
a plurality of detachable fixing parts (118a) mounted at one sides of the extending rails (118) to be spaced apart from each other at a predetermined interval, and configured to adsorb and fix the extending rails (118) to the outer surface of the vehicle, and
the solar panel mounting part (120) includes:
a pair of extending frames (121) having a wire structure that is wound around outer circumferential surfaces of both end portions of the winding roller (116), having a structure of which a position is changed along the extending rails (118), and bound to both end portions of the solar cell panel (130) to fix a position of the solar cell panel (130); and
spacing frames (122) mounted between the pair of extending frames (121) in an integrated structure, and configured to maintain an interval between the pair of extending frames (121) at a predetermined distance.

4. The vehicle of claim 2, wherein the fifth accommodation parts (115) of the solar panel accommodation part (110) are sequentially mounted to be adjacent to each other in an independent form by 1,000 to 1,400 mm along the side surface of the vehicle,
the solar cell panels (130) are mounted in a form of which portions of both end portions are engaged with each other to overlap each other, and
both end portions of the solar cell panels (130) overlapping each other according to the user's intention are unfolded and sequentially disposed.

5. The vehicle of claim 1, wherein the vehicle includes:
a sunlight amount detector (151) mounted on the outer surface of the vehicle to detect an amount of sunlight incident thereon in real time, and transmit detected data to the controller;
a weather information acquisition part (152) mounted in the vehicle and linked to an Internet network to receive real-time weather information and transmit the real-time weather information to the controller (140);
a position change part (153) mounted on the outer surface of the vehicle, and configured to change a position of the solar panel accommodation part (110); and
an angle change part (154) configured to change a mounting angle of the solar cell panels (130) mounted on the solar panel mounting part (120), and
the controller (140) controls operations of the solar panel accommodation part (110), the position change part (153), and the angle change part (154) using the sunlight amount detector (151) and the weather information acquisition part (152), has a built-in wireless communication module (141) interworking with a user's smart device, and provides an operation state of the solar panel accommodation part (110) and a production state of electricity produced from the solar cell panels (130) to the user's smart device using the wireless communication module (141).
